(19) United States
(12) Patent Application Publication
(10) Pub. No.: US 2006/0139708 A1
(43) Pub. Date: Jun. 29, 2006

(54) Method for correcting the response of charge coupled device

(75) Inventor: Wei-Qi Li, Beijing (CN)

Correspondence Address: APEX JURIS, PLLC;TRACY M HEIMS, LAKE CITY CENTER, SUITE 410, 12360 LAKE CITY WAY NORTHEAST, SEATTLE, WA, 98125, US

(73) Assignee: Destiny Technology Corporation, Taipei (TW)

(21) Appl. No.: 11/021,188

(22) Filed: Dec. 23, 2004

(51) Int. Cl. G03F 3/08

(52) U.S. Cl. 358/519

(57) ABSTRACT

A method for correcting pixel digital response of a charge coupled device (CCD) is provided. First, fetch black reference values and white reference values of each pixel of the CCD. Then, calculate gain values according to the black and white reference values. Further, generate and store a correction table according to the black reference values and the gain values. Finally, adjust and get a correction value from a real response of the CCD according to the correction table. Therefore, the CCD response is corrected and improved.

### FIELD OF THE INVENTION

The invention generally relates to a correction method, and in particular relates to a method for correcting the response of a charge coupled device (CCD).

### BACKGROUND OF THE INVENTION

Charge coupled devices (CCD) are being currently and widely used as image detecting elements. Charge coupled devices use photodiodes to convert light into electricity so that images are converted into digital data. Photodiode is a kind of semiconductor device that processes image pixel. A single-CCD camera is a camera including only a unit of CCD to convert both luminosity and color signals. Therefore, a tri-CCD camera is a camera having three units of CCD. The light passing through a special prism is separated into R (red), G (green) and B (blue) color lights. Each color light is processed by a CCD and converted into electrical signal. Then, an electrical circuit processes the signals into image signal, thus form a 3CCD system. In comparison with single-CCD, 3CCD separately uses three CCD units to convert red, green and blue signals, the photograph color reverted from the image signals is more accurate and natural than that from a single-CCD, the clarity and the signal to noise ratio is higher, the sensitivity is better, and the dynamic operation range is also wider. FIG. 1 shows R, G, B outputs of a linear CCD.

The electrical signal from each pixel of the CCD is transferred orderly to the next pixel and outputted from the bottom portion, then amplified by an amplifier at the rim of the CCD.

The CCD imaging pixels are arranged in an X-Y array. Each pixel is composed of a photodiode and an adjacent serial buffer. The photodiode converts the photons of light into electrons that reflect the brightness of that pixel. The whole image electrons are gained at the same time and shifted off the CCD array using electron diffusion with a voltage gradient. The image is scanned through the serial buffer, amplified and shifted into an A to D converter so as to get a low noise, high performance image.

However, the image from CCD is usually imperfect that requires color correction. Each CCD unit has its response characteristics that even CCDs of the same model from a same maker have differences when processing the same image. Some serious imaging problems coming from deviation of pixels in the linear CCD, uneven illumination in the scanning environment and non-uniform components in the CCD make the output signal weak or defective that requires correction. Therefore, the correction is to adjust the color response to meet some standardized reference values so that the inputs can be transformed into qualified color outputs. Conventional correction manner is to use a multiplier and several gain ranges and reference values to adjust the gains into suitable ranges. However, this method is not well effective for CCD correction.

### SUMMARY OF THE INVENTION

In order to solve the above problems, the object of the invention is to provide a method for correcting a CCD in which the optoelectronic signals are corrected so as to enhance the pixel response of the CCD.

In order to achieve the aforesaid objective, the method for correcting the response of a charge coupled device is provided. First fetches the black reference values and white reference values of each pixel of the CCD. Then, calculate the gain values according to the black and white reference values. Further, generate and store a correction table according to the black reference values and the gain values. Finally, adjust and get a correction value from the real response of the CCD according to the correction table. Therefore, the CCD response is corrected and improved.

### BRIEF DESCRIPTION OF THE DRAWINGS

The invention will become more fully understood from the detailed description given herein below. However, this description is for purposes of illustration only, and thus is not limitative of the invention, wherein:

FIG. 1 is descriptive view of pixel output of a conventional linear CCD;

FIG. 2 is a flowchart of CCD correction method of the invention;

FIG. 3 is a response diagram of a CCD; and

FIGS. 4A to 4F are embodiments of storage formats of correction table according to the invention.

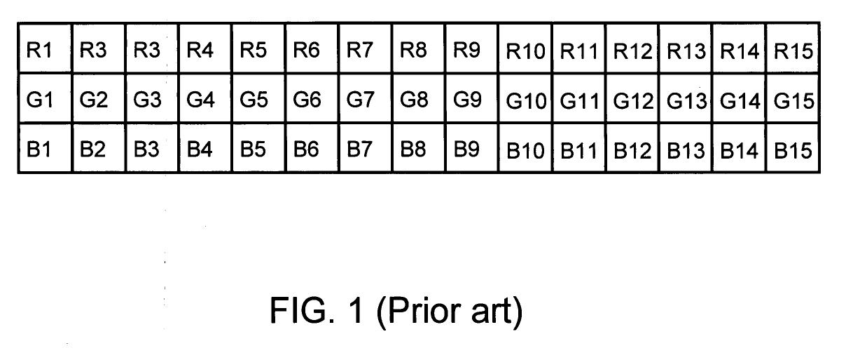

### DETAILED DESCRIPTION OF THE INVENTION

Basically, each imaging pixel of a CCD performs a function of outputting voltage relative to the received optical energy in a linear way. However, the constant in the linear function has to be adjusted according to the variation of the pixels. Besides, the additional error caused by uneven illumination and non-uniform components in the CCD can be corrected through a linear transformation of each pixel.

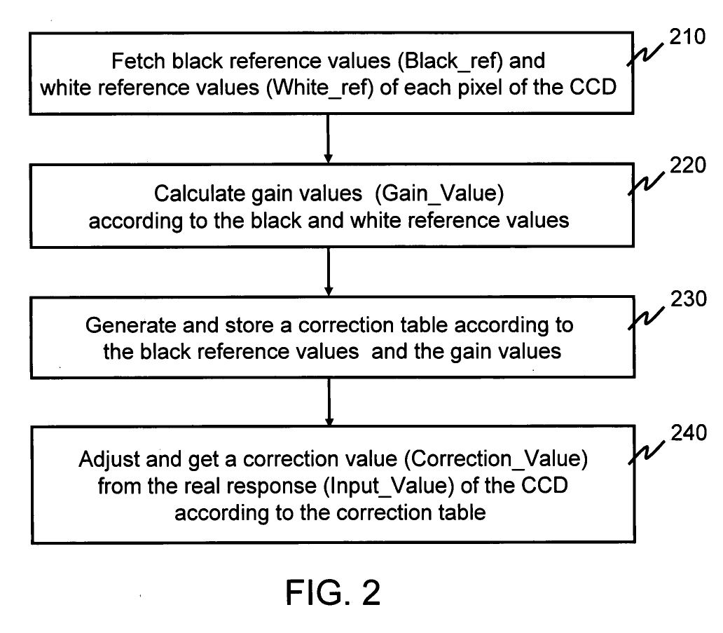

As shown in FIG. 2, a flowchart of CCD response correction method of the invention, the method includes the following steps. First, fetching the black reference values Black_ref and white reference values White_ref of each pixel of the CCD (step 210). Then, calculating the gain values Gain_Value according to the black and white reference values Black_ref, White_ref (step 220). Further, generating and storing a correction table according to the black reference values Black_ref and the gain values Gain_Value (step 230). Finally, adjusting and getting a correction value Correction_Value from the real response Input Value of the CCD according to the correction table (step 240).

The first step is to fetch the black reference values Black_ref and white reference values White_ref of each pixel of the CCD. Then, check the relationship between the real response and the ideal response of the CCD.

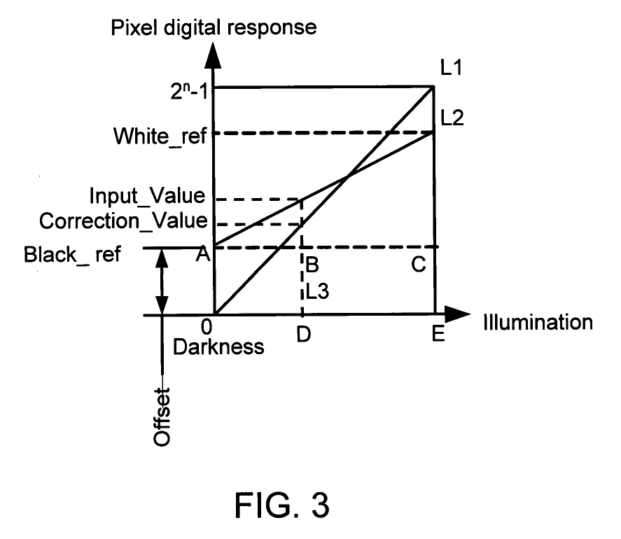

FIG. 3 shows the output response of a CCD unit. Ideally, the pixel digital response is linearly relative to the illumination of light. The ideal response line L1 passes the origin O with a slope 1. That is, the response is 0 when the illumination is 0, and the response increases as the illumination increases. However, the real response line as L2 has a black reference value Black_ref at dark (the illumination is 0), and a white reference value White_ref at a maximum illumination. For description, let us take a vertical line L3 crossing a horizontal line AC at B and crossing the horizontal axis at D. The line AC passes the starting point A of the real response line L2. The vertical line L3 represents a certain illumination that, at the specific illumination D, the real response Input_Value of the CCD is different from an ideal response or correction value Correction_value. The relationship is as follows:

$$\frac{Input\_Value - Black\_ref}{White\_ref - Black\_ref} = \frac{AB}{AC} = \frac{OD}{OE} = \frac{Correction\_Value}{{2}^{n} - 1} \\ so that , \\ Correction\_Value = ( {2}^{n} - 1 ) \frac{Input\_Value - Black\_ref + offset}{White\_ref - Black\_ref} \qquad Formula 1$$

wherein the “Offset” is an offset value to avoid that the correction value Correction_Value is negative.

The formula 1 can be simplified as:

$$Correction\_Value = Gain\_Value ( Input\_Black \_ref ) in which Gain\_Value = \frac{{2}^{n} - 1}{White\_ref - Black\_ref} \qquad Formula 2$$

is a constant, and the n is a positive integer.

Therefore, according Formula 2, the correction value Correction_Value can be calculated from the real response Input_Value, the gain values Gain_Value and the black reference value Black_ref.

The gain values Gain_Value and the black reference value Black_ref are pre-determined and stored in a correction table in memory, such as DRAM. The correction values are stored in a SCCR register in three formats of one-byte, two-byte and three-byte as in Table 1.

TABLE 1

| Byte Format | Operations |
|---|---|
| 1-byte | 8 bits gain |
| 2-byte | 8 bits black value + 8 bits gain |
| | 7 bits black value + 9 bits gain |
| | 6 bits black value + 10 bits gain |
| | 4 bits black value + 12 bits gain |
| 3-byte | 12 bits black value + 12 bits gain |

The operation for 1-byte value is only 8 bits gain. The operations for two-byte values include four combinations (16 bits in total) of black reference value Black_ref and gain value Gain_Value. The operation for three-byte value is an addition of 12 bits black reference value Black_ref and 12 bits gain values Gain_Value. Therefore, the corrections for CCD may include both gain correction and black reference value correction, or just the gain correction.

The black reference value of each pixel is first calculated by sum of black reference value and black value offset stored in the BLCR register. The black reference value is increased by multiplication of *1, *2, *4, *8, *16, then subtracted by the real response Input_Value. Then, performing post-scaling by multiplication of the black reference value and *1, *2, *4, *8, *16. Finally, correcting the pixel response with a suitable multiplication according to a gain range defined in the SCCR register.

Supposing the gain range is defined of 8 bits, the adjustment range is defined as * 1 to *5. For convenience of use, the gain value Gain_Value is encoded as a gain value in the table Table Gain Value, as shown in Table 2.

TABLE 2

| Shading Value | Gain |
|---|---|
| 0 | 1.000 |
| 1 | 1.020 |
| 2 | 1.039 |
| 3 | 1.059 |
| . | . |
| . | . |
| . | . |
| 250 | 4.900 |
| 251 | 4.920 |
| 252 | 4.940 |
| 253 | 4.960 |
| 254 | 4.979 |
| 255 | 4.999 |

The relationship is:
Gain_Value=2ⁿ (Gain_Value−1)|_{n=6,7,8,9,11,12} Formula 3
in which
Shading_Value=Table_Gain_Value; and
Gain=Gain_Value.

The number n is determined by:
Max_Table_Gain_Value=2ⁿ (Max_Gain_Value−1)|_{n=6,7,8,9,10,11,12}·

For an 8-bit encoding, the “Max_Table_Gain_Value” is 255. When the “Max_Gain_Value” is 5, Formula 3 is transformed into:

$$Gain\_Value = 1 + \frac{Table\_Gain \_Value}{{2}^{n}} . \qquad Formula 4$$

From formula 4 and formula 2, we get that:

$$Correction\_Value = ( Input\_Value - Black\_ref ) ( 1 + \frac{Table\_Gain \_Value}{{2}^{n}} ) . \qquad Formula 5$$

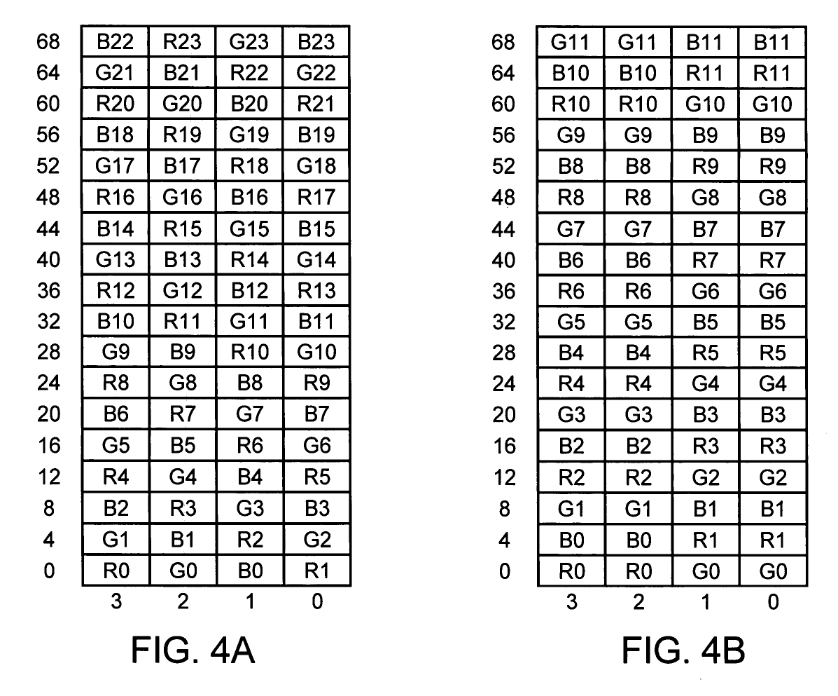

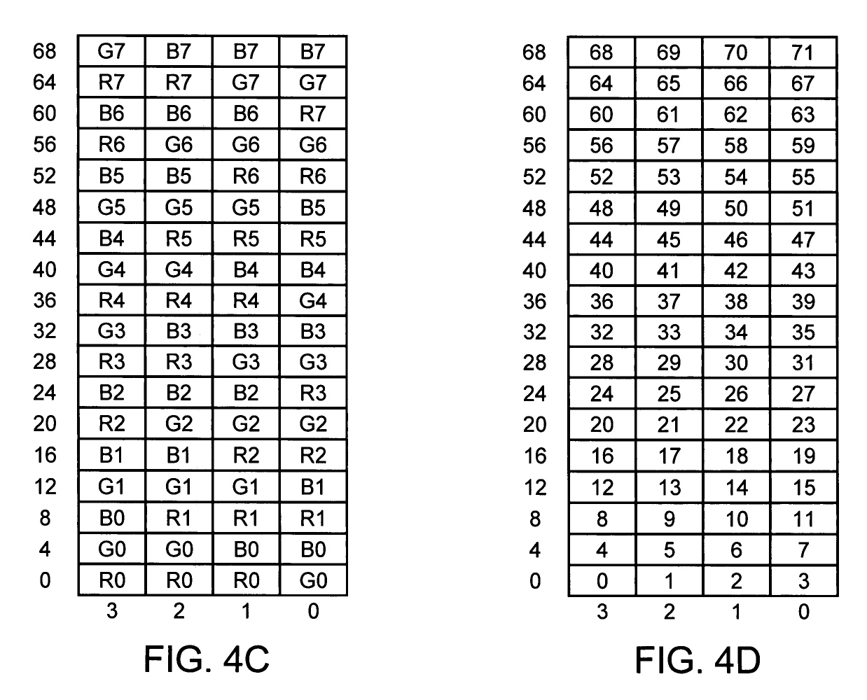

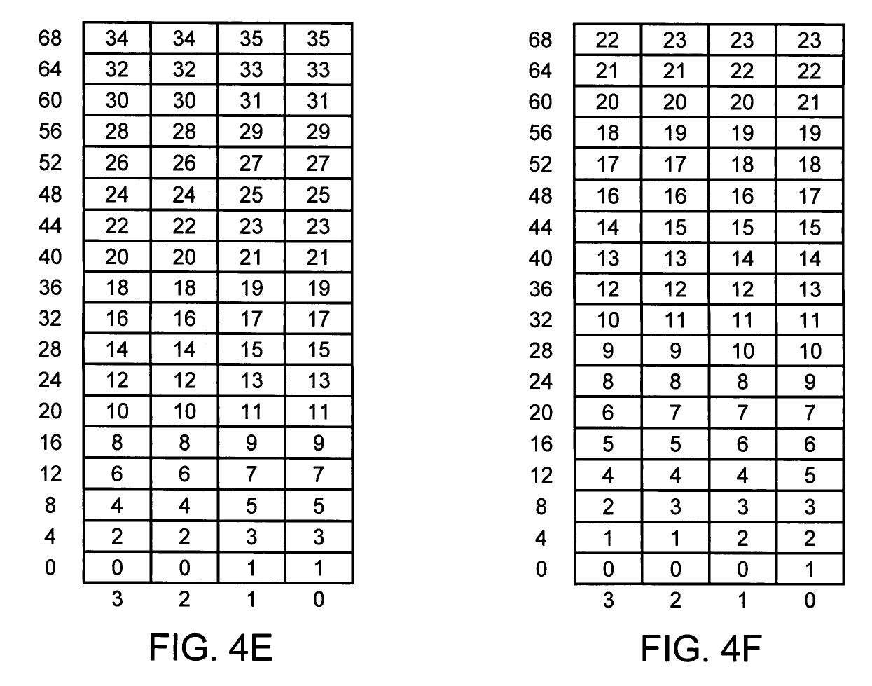

The invention uses the formula 5 to get correction values. The black reference value Black_ref and the gain value in the table Table_Gain_Value are all stored in the correction table in memory. The formats of the correction table are shown in FIG. 4A to FIG. 4F, in which FIGS. 4A to 4C are respective examples of one-byte, two-byte and three-byte color modes, in where R is a red color light, G is a green color light, and B is a blue color light; and FIGS. 4E to 4F are respective examples of one-byte, two-byte and three-byte monochrome modes. To get the correction value Correction_value, the black reference value Black_ref and the gain value in the table Table_Gain_Vallue are fetched from the correction table in memory and applied to the formula 5 with the real response Input_Value.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A method for correcting pixel digital response of a charge coupled device (CCD), comprising steps of:
fetching black reference values and white reference values of each pixel of the CCD;
calculating gain values according to the black and white reference values;
generating and storing a correction table according to the black reference values and gain values; and
adjusting and getting a correction value from a real response of the CCD according to the correction table.

2. The method of claim 1, wherein the gain value is obtained by:
$$Gain\_Value = \frac{{2}^{n} - 1}{White\_ref - Black\_ref} ;$$
wherein the White_ref is the white reference value, the Black_ref is the black reference value, and the n is a positive integer.

3. The method of claim 1, wherein a gain value in the table is obtained by:
Table_Gain_Value=2ⁿ (Gain_value−1)|_{n=6,7,8,9,10,11,12};
wherein the n is determined by:
Max_Table_Gain_Value=2ⁿ (Max_Gain_Value−1)|_{n=6,7,8,9,11,12};
wherein the Max_Table_Gain_Value is a maximum gain encoded value in the table, and the Max_Gain_Value is the maximum gain value.

4. The method of claim 3, wherein the Max_Gain_Value is chosen from 2, 3 and 5.

5. The method of claim 1, wherein the correction value is obtained by:
$$Correction\_Value = ( Input\_Value - Black\_ref ) ( 1 + \frac{Table\_Gain \_Value}{{2}^{n}} ) ;$$
wherein the Input_Value is the real response, the Black_ref is the black reference value, and the Table_Gain_Value is the gain value in the table.

6. The method of claim 1, wherein values in the correction table are chosen from one-byte, two-byte and three-byte formats.

7. The method of claim 6, wherein a one-byte format correction value is operated with 8-bit the gain value in the table; a two-byte format value is operated with totally 16-bit the black reference value and the gain value in the table; and a three-byte format value is operated with 24-bit the black reference value and the gain value in the table.

8. The method of claim 1, further comprising a step of encoding the gain values into the gain values in the table after the step of calculating the gain values according to the black and white reference values.
